(19) United States
(12) Patent Application Publication
(10) Pub. No.: US 2024/0336839 A1
(43) Pub. Date: Oct. 10, 2024

(54) TiN ETCHANT COMPOSITION AND METHOD OF FORMING SEMICONDUCTOR DEVICE

(71) Applicant: Samsung Electronics Co,. Ltd., Suwon-si (KR)

(72) Inventors: GAYOUNG SONG, Suwon-si (KR); JUNG-MIN OH, Suwon-Si (KR); TAE SOO KWON, Seongnam-si (KR); JUN-EUN LEE, Seongnam-si (KR); SANG WON BAE, Suwon-si (KR); Minjae SUNG, Suwon-si (KR); YOUN SUG YOO, Seongnam-si (KR); WOOK CHANG, Seongnam-si (KR)

(73) Assignees: Samsung Electronics Co,. Ltd., Suwon-si (KR); OCI Company Ltd., Seoul (KR)

(21) Appl. No.: 18/508,941

(22) Filed: Nov. 14, 2023

(30) Foreign Application Priority Data
Apr. 5, 2023 (KR) 10-2023-0044966

(51) Int. Cl. C09K 13/06; H01L 21/3213; H01L 21/768

(52) U.S. Cl. CPC C09K 13/06; H01L 21/32134; H01L 21/76841

(57) ABSTRACT

A titanium nitride etchant composition and a method of forming a semiconductor device using the same are provided. The titanium nitride etchant composition includes hydrogen peroxide, phosphoric acid, and an amine compound, wherein the amine compound includes two or more nitrogen atoms.

### CROSS-REFERENCE TO RELATED APPLICATIONS

This U.S. non-provisional patent application claims priority under 35 U.S.C. § 119 to Korean Patent Application No. 10-2023-0044966, filed on Apr. 5, 2023, in the Korean Intellectual Property Office, the entire contents of which are hereby incorporated by reference.

### BACKGROUND OF THE INVENTION

The present disclosure relates to a titanium nitride etchant composition and a method of forming a semiconductor device using the same.

As semiconductor devices have become highly integrated, lines and spaces of interconnections in the semiconductor devices have been reduced. Thus, fine-patterning techniques may be desirable in processes for fabricating the interconnections. In addition, low resistances of the interconnections may be beneficial. Interconnection materials may include titanium, tantalum, aluminum, and tungsten.

### SUMMARY

An object of the present disclosure is to provide a semiconductor device with improved integration and a method of manufacturing the same.

An object of the present disclosure is to provide a method of forming a semiconductor device having improved reliability.

A titanium nitride etchant composition according to some embodiments of the present disclosure includes hydrogen peroxide, phosphoric acid, and an amine compound, and the amine compound includes two or more nitrogen atoms.

A titanium nitride etchant composition according to some embodiments of the present disclosure includes hydrogen peroxide in an amount of 1 to 30 wt. %, phosphoric acid in an amount of 20 to 80 wt. %, and an amine compound in an amount of 0.01 to 10 wt. %.

A method of forming a semiconductor device according to some embodiments of the present disclosure includes sequentially stacking a titanium nitride layer and a tungsten layer on a substrate, exposing the titanium nitride layer by partially removing the tungsten layer, and supplying a titanium nitride etchant composition to remove the titanium nitride layer exposed next to the tungsten layer, the titanium nitride etchant composition includes hydrogen peroxide, phosphoric acid, and an amine compound, and the amine compound includes two or more nitrogen atoms.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A to 1C are cross-sectional views illustrating a method of forming a semiconductor device according to embodiments.

### DETAILED DESCRIPTION

A titanium nitride etchant composition may include hydrogen peroxide, phosphoric acid, and an amine compound, wherein the amine compound may be a polyvalent amine compound containing two or more nitrogen atoms. The amine compound may include two or more amino groups (—NH₂), such as a diamine, triamine, tetraamine, etc. The amine compound may be at least one of 1,3-diaminopropane, 1,8-diamino-4-azaoctane, tetraethylene pentamine, polyethyleneimine, and tris (2-aminoethyl) amine.

The amine compound may have at least one structure of

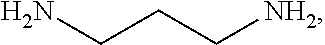

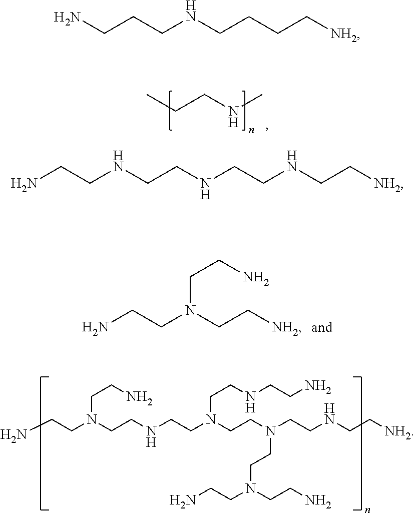

An amount of the hydrogen peroxide may be 1 to 30 wt. % based on a total weight of the composition, an amount of the phosphoric acid may be 20 to 80 wt. % based on the total weight of the composition, and an amount of the amine compound may be 0.01 to 10 wt. % based on the total weight of the composition. The titanium nitride etchant composition may further include water. An amount of the water may be 10 to 78.99 wt. % based on the total weight of the composition.

The titanium nitride etchant composition may be applied to a structure in which a titanium nitride layer and a tungsten layer are simultaneously exposed, and the titanium nitride etchant composition may etch the titanium nitride layer such that an etching selectivity of the titanium nitride layer to the tungsten layer is 2.6 to 100, for example an etching selectivity greater than 3.0, such as greater than 10.0 (e.g., from 12 to 30).

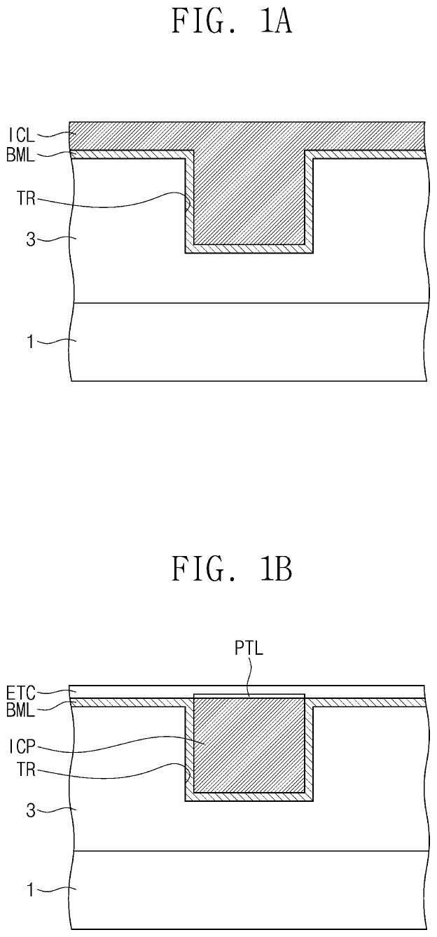

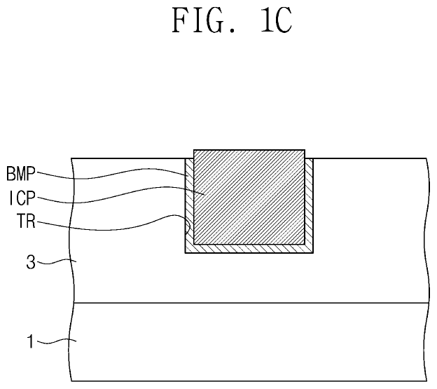

FIGS. 1A to 1C are cross-sectional views illustrating a method of forming a semiconductor device according to embodiments.

Referring to FIG. 1A, an interlayer insulating layer 3 is formed on a substrate 1. The substrate 1 may be a silicon single crystal wafer, a silicon epitaxial layer, or a silicon on insulator (SOI) substrate, or other wafer or layer. The interlayer insulating layer 3 may have a single layer or multilayer structure of at least one silicon compound (e.g., silicon oxide, silicon nitride, silicon oxynitride), and a porous insulator. At least a portion of the interlayer insulating layer 3 is etched to form a trench TR. A titanium nitride layer BML and a tungsten layer ICL are sequentially stacked on the interlayer insulating layer 3. The titanium nitride layer BML may also be referred to as an ‘anti-diffusion layer’. The titanium nitride layer BML may conformally cover an inner wall and a bottom surface of the trench TR and an upper surface of the interlayer insulating layer 3. The tungsten layer ICL may also be referred to as an ‘interconnection layer’. The tungsten layer ICL may fill the trench TR.

Referring to FIGS. 1A and 1B, a chemical mechanical polishing (CMP) process or a front etch back process is performed to remove the tungsten layer ICL outside the trench TR and to form a tungsten pattern ICP in the trench TR. The tungsten pattern ICP may also be referred to as a ‘tungsten layer’ or an ‘interconnection pattern’. The tungsten layer ICL may be removed next to the trench TR, and the titanium nitride layer BML may be exposed.

Referring to FIGS. 1B and 1C, an etching process is performed by supplying a titanium nitride etchant composition ETC of the present disclosure on the titanium nitride layer BML. Through the etching process, the titanium nitride layer BML outside the trench TR is removed to expose an upper surface of the interlayer insulating layer 3 and to form the titanium nitride pattern BMP in the trench TR. The providing of the etchant composition ETC may be performed by a spray using a nozzle, an injection spin coating, or a dipping process.

The titanium nitride etchant composition ETC may cover the titanium nitride layer BML and the tungsten pattern ICP to form a layer. Hydrogen peroxide in the titanium nitride etchant composition ETC may oxidize or etch surfaces of the titanium nitride layer BML and the tungsten pattern ICP. Phosphoric acid in the titanium nitride etchant composition ETC may etch the surfaces of the titanium nitride layer BML and the tungsten pattern ICP. An amine compound in the titanium nitride etchant composition ETC forms a protective layer PTL on the surface of the tungsten pattern ICP. The protective layer PTL may be a positive charge layer including an amine compound. The amine compound included in the titanium nitride etchant composition ETC according to the present disclosure includes two or more nitrogen atoms (or two or more amino groups (—NH₂)), such that the protective layer PTL is capable of being easily forming. The protective layer PTL may protect the surface of the tungsten pattern ICP from being etched by hydrogen peroxide and phosphoric acid of the titanium nitride etchant composition ETC. As a result, an etching loss of the tungsten pattern ICP constituting an interconnection may be small, thereby accurately forming the interconnection pattern. In addition, the interconnection pattern may have a desired thickness, and an electrical resistance may not increase, thereby forming a semiconductor device with improved reliability. A cleaning process may be performed after the etching process.

In the following, experimental examples will be described.

### COMPARATIVE EXAMPLE 1

In Comparative Example 1, compositions containing only hydrogen peroxide and phosphoric acid without adding an amine compound were prepared in various compositions. In addition, when these compositions were applied, etching rates of titanium nitride and tungsten were obtained and recorded in Table 1. For Comparative Example 1, bare wafers on which a titanium nitride layer was formed and bare wafers on which a tungsten layer was formed were prepared.

TABLE 1

| | hydrogen | | | etch rate of | | titanium |
|---|---|---|---|---|---|---|
| | peroxide | phosphoric | water | TiN | etch rate of | nitride/tungsten |
| | (wt. %) | acid (wt. %) | (wt. %) | (Å/min) | W (Å/min) | selectivity |
| Composition | 2 | 0 | 98 | 33.73 | 208.33 | 0.16 |
| 1 | | | | | | |
| Composition | 2 | 5 | 93 | 35.88 | 54.41 | 0.66 |
| 2 | | | | | | |
| Composition | 2 | 10 | 88 | 45.81 | 49.99 | 0.92 |
| 3 | | | | | | |
| Composition | 2 | 40 | 58 | 57.13 | 34.79 | 1.64 |
| 4 | | | | | | |
| Composition | 2 | 60 | 38 | 66.45 | 27.15 | 2.45 |
| 5 | | | | | | |

Referring to Table 1, it may be seen that composition 1 containing only hydrogen peroxide without phosphoric acid has a much higher etching rate of tungsten than titanium nitride, making it very unsuitable. As a content of phosphoric acid increases, the titanium nitride/tungsten selectivity ratio increases, but it may be seen that there is a limit to adjusting the selectivity to around 2.5 using only phosphoric acid and hydrogen peroxide.

### Experimental Example 1

In this example, an additive was added to the titanium nitride etchant composition to test whether there was a change in the titanium nitride/tungsten selectivity, and the experimental composition and results were recorded in Table 2.

TABLE 2

| | | | | | etch | etch | titanium |
|---|---|---|---|---|---|---|---|
| | hydrogen | phosphoric | | | rate of | rate of | nitride/ |
| | peroxide | acid | type and content (wt. %) | water | TiN | W | tungsten |
| | (wt. %) | (wt. %) | of additive | (wt. %) | (Å/min) | (Å/min) | selectivity |
| Composition 5 | 2 | 60 | — | 38 | 66.45 | 27.15 | 2.45 |
| Composition 6 | 2 | 60 | ethyl alcohol 1.0 wt. % | 37 | 64.43 | 28.79 | 2.24 |
| Composition 7 | 2 | 60 | 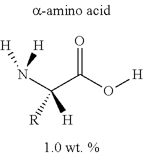 | 37 | 67.15 | 25.19 | 2.67 |
| Composition 8 | 2 | 60 | 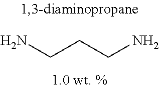 | 37 | 55.26 | 18.64 | 2.96 |

Referring to Table 2, in Composition 6, 1.0 wt. % of ethyl alcohol was added as an additive, but the titanium nitride/tungsten etching selectivity dropped to 2.24 compared to Composition 5. In Composition 7, α-amino acid was added in an amount of 1.0 wt. % as an amine compound containing one nitrogen atom (or amino group (—NH₂)) as an additive. In the case of Composition 7, the titanium nitride/tungsten etching selectivity was increased to 2.67 compared to Composition 5, but it differed from Composition 5 by only about 0.2. In Composition 8, as an additive, 1,3-diaminopropane was added in an amount of 1.0 wt. % as an amine compound containing two nitrogen atoms (or amino groups (—NH₂)). In the case of composition 8, the titanium nitride/tungsten etching selectivity was 2.96, which was increased to 0.5 times or more compared to the case of Composition 5. Through these experiments, it may be seen that adding the amine compound containing two nitrogen atoms (or amino groups (—NH₂)) as an additive is beneficial for increasing the titanium nitride/tungsten etching selectivity.

### Experimental Example 2

In this example, after variously changing the type of amine compound as an additive, it was tested whether there was a change in the titanium nitride/tungsten selectivity, and the experimental composition and results were recorded in Table 3.

TABLE 3

| | | | | | etch | etch | titanium |
|---|---|---|---|---|---|---|---|
| | hydrogen | phosphoric | | | rate of | rate of | nitride/ |
| | peroxide | acid | | water | TiN | W | tungsten |
| | (wt. %) | (wt. %) | type and content (wt. %) of additive | (wt. %) | (Å/min) | (Å/min) | selectivity |
| Composition 8 | 2 | 60 | 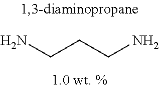 | 37 | 55.26 | 18.64 | 2.96 |
| Composition 9 | 2 | 60 | 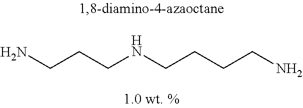 | 37 | 54.34 | 13.62 | 3.99 |
| Composition 10 | 2 | 60 | 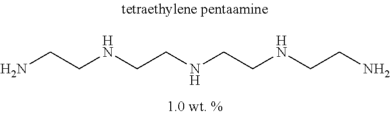 [SMILES: NCCNCCNCCNCCN] | 37 | 48.12 | 6.59 | 7.3 |
| Composition 11 | 2 | 60 | polyethylene imine 1.0 wt. % | 37 | 40.12 | 2.33 | 17.22 |

In Table 3, a structure of polyethyleneimine may be a linear structure of

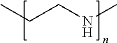

or a branched structure of

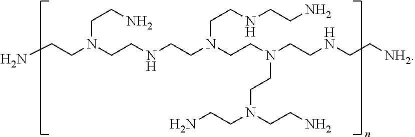

In Composition 9, 1,8-diamino-4-azaoctane, which is an example of an amine compound containing three nitrogen atoms (or amino groups (—NH₂)), was added at 1.0 wt. % as an additive. In Composition 10, tetraethylene pentamine was added in an amount of 1.0 wt. %, which is an example of an amine compound containing 5 nitrogen atoms (or amino groups (—NH₂)), as an additive. polyethylene imine, an additive used in Composition 11, may contain tens to tens of thousands of nitrogen atoms (or amino groups (—NH₂)). In Experimental Example 2, it may be seen that the titanium nitride/tungsten selectivity increases as the number of nitrogen atoms (or the atomic percent of nitrogen) in the amine compound increases.

As described above, when the titanium nitride etchant composition according to the present disclosure is used, only titanium nitride may be selectively etched in a structure in which titanium nitride and tungsten are exposed together.

Although not disclosed in Experimental Example 2, and tris (2-aminoethyl) amine having a structure of Formula 1 below may also be used as an amine compound included in the titanium nitride etchant composition of the present disclosure.

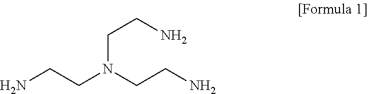

The titanium etchant composition according to the present disclosure may etch the titanium nitride layer such that the etching selectivity of the titanium nitride layer with respect to the tungsten layer is 2.9 to 300. The titanium nitride etchant composition has the excellent etching selectivity of the titanium nitride layer with respect to the tungsten layer, and when applied to the method of forming the semiconductor device, the unnecessary diffusion barrier may be removed while reducing loss of the main interconnection. As a result, the interconnection may be accurately formed and the electrical resistance may be lowered, thereby forming the semiconductor device with the improved reliability.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A titanium nitride etchant composition comprising:
hydrogen peroxide;
phosphoric acid; and
an amine compound,
wherein the amine compound includes two or more nitrogen atoms.

2. The titanium nitride etchant composition of claim 1, wherein the amine compound includes two or more amino groups (—NH₂).

3. The titanium nitride etchant composition of claim 1, wherein the amine compound is at least one of 1,3-diaminopropane, 1,8-diamino-4-azaoctane, tetraethylene pentamine, polyethylene imine, and tris (2-aminoethyl) amine.

4. The titanium nitride etchant composition of claim 1, wherein the amine compound has a structure of at least one of

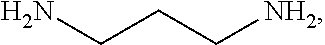

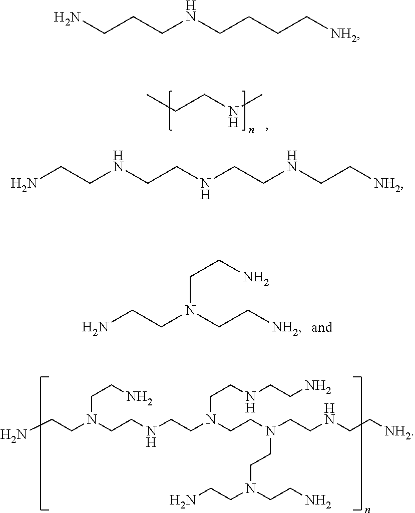

5. The titanium nitride etchant composition of claim 1, wherein an amount of the hydrogen peroxide is 1 to 30 wt. % based on a total weight of the composition,
wherein an amount of the phosphoric acid is 20 to 80 wt. % based on the total weight of the composition, and
wherein an amount of the amine compound is 0.01 to 10 wt. % based on the total weight of the composition.

6. The titanium nitride etchant composition of claim 1, further comprising water.

7. The titanium nitride etchant composition of claim 6, wherein an amount of the water is 10 to 78.99 wt. % based on a total weight of the composition.

8. The titanium nitride etchant composition of claim 1, wherein the titanium nitride etchant composition is applied to a structure in which a titanium nitride layer and a tungsten layer are simultaneously exposed, and
wherein the titanium nitride etchant composition is used to etch the titanium nitride layer such that an etching selectivity of the titanium nitride layer to the tungsten layer is 2.9 to 300.

9. A titanium nitride etchant composition comprising:
hydrogen peroxide in an amount of 1 to 30 wt. %;
phosphoric acid in an amount of 20 to 80 wt. %; and
an amine compound in an amount of 0.01 to 10 wt. %.

10. The titanium nitride etchant composition of claim 9, wherein the amine compound includes two or more amino groups (—NH₂).

11. The titanium nitride etchant composition of claim 9, wherein the amine compound is at least one of 1,3-diaminopropane, 1,8-diamino-4-azaoctane, tetraethylene pentamine, polyethylene imine, and tris (2-aminoethyl) amine.

12. The titanium nitride etchant composition of claim 9, wherein the amine compound has at least one structure of

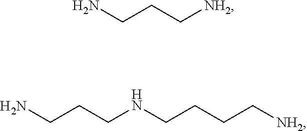 [SMILES: NCCCN ; NCCCCNCCCN]

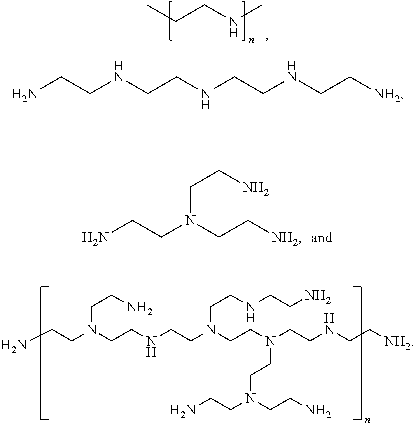

13. The titanium nitride etchant composition of claim 9, further comprising water in an amount of 10 to 78.99 wt. %.

14. A method of forming a semiconductor device, the method comprising:
sequentially stacking a titanium nitride layer and a tungsten layer on a substrate;
exposing the titanium nitride layer by partially removing the tungsten layer; and
supplying a titanium nitride etchant composition to remove the titanium nitride layer exposed next to the tungsten layer,
wherein the titanium nitride etchant composition includes hydrogen peroxide, phosphoric acid, and an amine compound, wherein the amine compound includes two or more nitrogen atoms.

15. The method of claim 14, wherein the amine compound includes two or more amino groups (—NH₂).

16. The method of claim 14, wherein the amine compound is at least one of 1,3-diaminopropane, 1,8-diamino-4-azaoctane, tetraethylene pentamine, polyethylene imine, and tris (2-aminoethyl) amine.

17. The method of claim 14, wherein the amine compound has a structure of at least one of

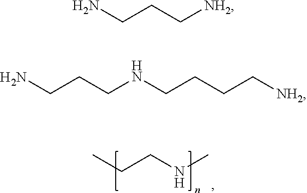

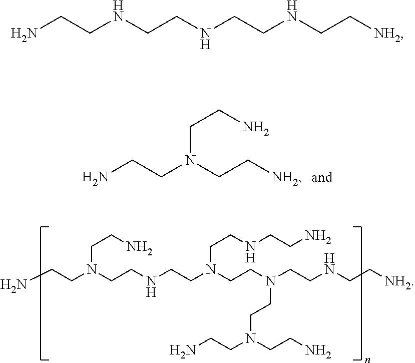

18. The method of claim 14, wherein an amount of the hydrogen peroxide is 1 to 30 wt. % based on a total weight of the composition,
wherein an amount of the phosphoric acid is 20 to 80 wt. % based on the total weight of the composition, and
wherein an amount of the amine compound is 0.01 to 10 wt. % based on the total weight of the composition.

19. The method of claim 14, further comprising water in an amount of 10 to 78.99 wt. % based on a total weight of the composition.

20. The method of claim 14, wherein the titanium nitride etching composition etches the titanium nitride layer such that the etching selectivity of the titanium nitride layer to the tungsten layer is 2.9 to 300.
